(19) United States
(12) Patent Application Publication
(10) Pub. No.: US 2021/0086158 A1
(43) Pub. Date: Mar. 25, 2021

(54) MICROWAVE ENHANCEMENT OF CHEMICAL REACTIONS

(71) Applicant: NuIonic Technologies LP, Portland, ME (US)

(72) Inventors: James M. Tranquilla, Lower Queensbury (CA); Jan H. Boshoff, Tulsa, OK (US)

(21) Appl. No.: 16/603,566

(22) PCT Filed: Apr. 4, 2018
(86) PCT No.: PCT/US2018/026044

§ 371 Date: Oct. 7, 2019

Related U.S. Application Data
(60) Provisional application No. 62/483,138, filed on Apr. 7, 2017.
(60) Provisional application No. 62/483,150, filed on Apr. 7, 2017.

(51) Int. Cl. B01J 12/00; B01J 19/12; B01J 19/00; B01J 35/04; B01J 8/42; B01J 8/18; B01J 8/00

(52) U.S. Cl. CPC B01J 12/002; B01J 2219/1206; B01J 19/0053; B01J 35/04; B01J 8/42; B01J 8/1818; B01J 8/001; B01J 2219/0875; B01J 2219/0892; B01J 2219/0896; B01J 2219/0898; B01J 2208/00442; B01J 2208/00902; B01J 2219/0036; B01J 2219/00747; B01J 19/126

(57) ABSTRACT

Gas streams may be effectively processed using microwave energy in such a way as to significantly reduce processing cost and plant complexity. In the first instance, microwave energy is used to generate a self-catalytic, non-equilibrium plasma, resulting in essentially complete gas reaction at industrial scales of operation. In the second instance, microwave energy is used in combination with conventional catalyst materials to significantly enhance their performance by enabling operation at reduced gas temperatures. In this second instance, the microwave energy may be used either to generate a non-equilibrium plasma or to selectively and directly heat the catalyst material.

### BACKGROUND OF THE INVENTION

### 1. Field of the Invention

The present invention relates to the improvement of chemical reactions that include the use of a catalyst. More particularly, the present invention relates to systems and methods using microwaves to enhance such chemical reactions.

### 2. Description of the Prior Art

The industrial use of microwave energy is now well established for over 50 years, with new applications continuing to be developed besides the historical operations of bulk heating. These include the development of microwave plasma techniques as well as the use of microwave energy to replace, stimulate or enhance the operation of conventional catalytic materials either in combination with plasma operations or in a non-plasma mode.

Plasma technology, although relatively recent in terms of some applications, has rapidly grown in popularity owing to the unique and impressive properties of plasmas, particularly in the promotion of some chemical processes either as the self-catalyst or in conjunction with other catalytic materials. In particular, the class of microwave plasmas is unique in that certain reactions occur only in the case of microwave plasmas (as opposed to other types of plasmas) and also because only microwave plasmas have the inherent capability to be scaled up to industrial levels.

The use of catalysts for the promotion of chemical processes is well established, so much so that an entire industry has developed worldwide for the development, sale and use of catalysts in virtually every area of chemical processing.

The potential use of microwave energy in combination with catalysts has been known for over 30 years, however published information deals only with low-power laboratory-scale reactor systems, citing the hurdles of achieving temperature uniformity and other technical issues at larger scale. There remains a practical need for systems capable of operating and controlling these processes at larger scales, compatible with commercial operations.

Microwave reactors, or applicators, have been in use for several decades in a wide variety of applications. In the most general terms, the reactor is the device in which the microwave energy is applied to the material(s) to be processed. These processes may be thermal or non-thermal, since microwave energy is capable of inducing heating (thermal) effects in most materials and it is also capable of electronically coupling to many molecular structures by means of direct electron (non-thermal) excitation.

Nearly all the microwave reactors introduced to date are small in scale compared to many conventional industrial processes. The obstacle of increasing the scale of operation of these reactors has usually been met by simply increasing the number of reactors, thereby increasing the size of the system. In many cases (e.g. drying or cooking materials such as food) this enlarged “linearization” of the system is entirely acceptable and fits well with other associated parts of the process. Nevertheless, there remains a challenge of increasing the unit capacity of the reactor without necessarily simply making the system bigger or adding more parts.

The geometrical size of a microwave reactor is limited by several factors, depending upon how the electromagnetic field is managed within it.

Cavity reactors cannot be smaller than the minimum size required to sustain the lowest order resonant mode at the microwave frequency being used, and they cannot generally exceed a certain size related to the penetration depth of the microwaves in the material being processed; this latter restriction may be greatly modified by arranging the material to move within the reactor such that substantially all of the material is sufficiently exposed to the microwave energy.

Travelling wave reactors may be sub-resonant, however there arises the need to quickly move the material being processed through the reactor electromagnetic field while still allowing sufficient time for the process to be completed to the desired degree. These systems are usually conveyorized or pneumatically driven.

Finally, the unit capacity of a microwave reactor is related to the maximum power of the microwave source that can be employed; depending on the frequency of operation within the industrial microwave frequency bands, this power limit may range from a few tens of watts up to approximately 100 kW.

### SUMMARY OF THE INVENTION

By means of the present disclosure, reactor designs are introduced that are capable of greatly increased material throughput, higher conversion efficiency and higher unit power capacity, hence significantly advancing the use of these systems for large-scale industrial applications.

One aspect of the present invention relates to a means of greatly increasing the unit capacity of microwave reactors that are of particular use in the processing of gases by means of plasma. The unit power capacity may be further significantly increased by providing a means of connecting more than one microwave generator to a single reactor.

A second aspect of the present invention relates to the combination of catalysts and microwave energy for the purpose of performing one or more chemical processes at a minimal energy cost. In the one instance, the combination is in the form of microwave plasma and catalysts, and in the other instance the combination is in the form of microwave energy (no plasma) and catalysts. This invention discloses beneficial and unique advantages of the synergy between catalysts and these (microwave energy and plasma) energy forms.

Plasmas consist of ions, electrons and charged molecular particles; plasma streams are highly chemically active due to their energetic species composition and are often self-catalytic, i.e. they can promote certain chemical operations at lower energy input than similar operations using non-plasma techniques.

Plasmas may be categorized as being either thermal or non-thermal, the distinguishing feature being the relative temperature of the gas with respect to the energy (equivalent temperature) of the electrons. Thermal plasmas are characteristically “hot”, meaning that the gas temperature is approximately equal to the electron temperature. Non-thermal plasmas (also known as non-equilibrium plasmas) are characterized as having gas temperature significantly less than the electron temperature.

In order to achieve minimum plasma energy, there are several operating conditions which must be simultaneously met:
1. Non-equilibrium conditions (T_{g}<<Tₑ) i.e. the gas temperature must be much less than the electron temperature,
2. Vibrational excitation (non-thermal),
3. Residence time in plasma <1 ms,
4. Reaction quench rate >10⁶ K/s,
5. Reaction zone pressure 100-150 Torr (13-20 kPa),
6. Excitation energy approximately 1 eV/molecule, ensuring condition 2 above
   Conditions 1, 2 and 6 above ensure that energy is not wasted in heat generation. Conditions 3 and 4 ensure that the gas molecules, once excited to form the desired products, do not become subject to reverse (or unwanted) chemical reactions; the products are effectively “frozen” in their converted state. Condition 5 is related to the “balance” between the internal plasma temperature and the cooler outer plasma region, essentially describing a “hybrid” plasma consisting of a hotter (thermal) internal part and a cooler (non-thermal) outer part.

Although it may not be practical to achieve all of the above conditions in every case, the maximum possible number of these conditions should be met in order to minimize reaction energy requirements.

In order to be commercially viable, plasma systems in this application must be capable of handling process gas volumes in the range of several hundred to several thousand Standard Liters per minute (SLPM). Furthermore, the plasma must operate in the non-thermal mode in order to achieve optimum energy efficiency. These constraints limit the plasma to essentially the microwave plasma type. Microwave plasma torches are capable of satisfying some of these constraints, however the presence of an electrode in this configuration leads to metal erosion, poor heat distribution and resultant added maintenance cost. The most satisfactory configuration is therefore one which has no electrode(s) and which generates a spatial plasma of sufficient volume and intensity to achieve commercial process flow rates.

Non-thermal plasmas produce ions, radicals and electronically excited species with internal energies that are often high enough to enhance plasma volume reactions. This can be attributed to the high threshold energies required to generate these species through electron collision processes. For ions and radicals, threshold energies of 5-20 eV are typically required and for electronically excited species, threshold energies are in the range of 1-10 eV. Vibrationally excited species are produced with the lowest threshold energies of 0.1-1 eV, hence the internal energies are too low to facilitate plasma volume reactions by themselves.

The importance of emphasizing the vibrationally excited species is that, of the three modes of molecular excitation (vibrational, rotational, translational), only the vibrational mode is non-thermal, i.e. no energy is consumed in the generation of heat, and hence it is the most energy efficient mode of excitation.

The simple configuration of a test tube mounted transversely (between the broad walls) in a rectangular waveguide, in which a gas is passed through the tube and is ionized (forming plasma) within the tube-waveguide intersection, is commonly used in laboratory situations. Such a configuration, however, is severely limited in size and gas throughput, being limited to typical gas flows of the order of a few liters per minute using microwave power levels of a few kilowatts. Such systems, although useful in laboratory operation, cannot practically be scaled up to industrial capacity.

A common improvement to the simple waveguide system referred above is the addition of a secondary, non-reagent gas flow upstream of the plasma (ionization) region, the purpose of said secondary gas flow being to form a vortex sheath which simultaneously constricts (stabilizes) the plasma gas to a narrow axial filament along the center of the reactor tube (where the microwave intensity is greatest) while forming a cooling sheath between the (hot) plasma and the tube wall, thereby protecting the tube from damaging thermal effects. This vortex arrangement, while providing plasma stability and thermal protection, often degrades the plasma process by introducing large quantities of non-reagent gas (such as Nitrogen, Argon, etc.) which must be subsequently removed from the product gas stream. Reactors such as described above can achieve complete gas conversion, however only within a narrow range of gas flow rate and power level; decreasing the power or increasing the gas flow leads to a rapid reduction ion gas conversion and, ultimately, to plasma extinction. For these reactor systems, the energy levels are in the range of 4-5 eV/molecule, indicating that these plasmas are not operating in the non-equilibrium mode (vibrational electron excitation) but rather in the thermal (plasma torch) mode.

The most significant improvement in microwave plasma operation came as the result of incorporating supersonic gas flow in combination with the simple waveguide plasma system described above. The characteristics of gas flow through a supersonic divergent nozzle are well understood and include a transfer of the gas rotational and translational energies into vibrational energy with a large increase in velocity. The energy transfer into the vibrational mode at the nozzle throat is accompanied by an extremely rapid cooling and drop in pressure sufficient to meet the necessary quench rate and pressure conditions described above for optimum (minimum energy) plasma operation.

The incorporation of the supersonic expansion nozzle and the waveguide plasma system results in a plasma apparatus wherein microwave energy contained in a waveguide conduit excites a plasma in a transversely-oriented second conduit, said second conduit within the boundary of the waveguide structure being essentially transparent to the microwave frequency being used such that microwave energy passes substantially unrestricted into the gas contained within the second conduit. The plasma so formed extends beyond the boundary of the waveguide, while being fully contained in the second conduit. Gas enters the reactor by means of an axial feed as well as by means of one or more tangential feeds. The purpose of the tangential feed(s) is to induce a vortex flow within the reactor plasma zone. Located immediately at the downstream end of the reactor is a supersonic nozzle of the type described earlier whose purpose is to quickly quench the plasma reactions. Thermal re-generation is controlled by adjusting the diverging nozzle angle to ensure critical heat transfer, i.e. plasma heat is transferred to the nozzle walls rather than being allowed to increase the gas temperature, thus reducing the gas flow to sub-sonic velocity. After leaving the nozzle the gas stream is further expanded at sub-sonic speed in a discharge vessel.

The arrangement in which the supersonic nozzle is located at the downstream end of the reactor as described above is preferred when the gas flow through the reactor is by means of presenting a vacuum pump or similar device at the exhaust end of the system, the significance being that the pressure in the plasma zone need not exceed atmospheric pressure; high pressure in the plasma zone acts to deter the formation of the plasma and may lead to erratic plasma operation.

Notwithstanding the improvements introduced by the above combination of supersonic expansion and microwave plasma, there remain the important restrictions of (i) introduction of a secondary vortex gas which requires subsequent removal, and (ii) restriction to low-pressure operation to avoid high gas pressure in the plasma zone.

In an attempt to overcome these further limitations, the supersonic nozzle may be moved upstream from the plasma zone; in this case the gas flow is maintained by applying high pressure at the nozzle inlet. Although the gas pressure is relatively high in the pre-supersonic, pre-plasma region, the action of the supersonic nozzle is to greatly reduce the pressure in the plasma zone, a desirable condition for plasma ignition and stability. The high velocity of the gas through the plasma region helps to meet the short-duration residence time in the plasma.

In order to confine and stabilize the plasma in the post-nozzle plasma region, a secondary gas is introduced to form a vortex sheath, however this secondary gas introduces the same limitation described earlier and hence represents a limitation to practical operation. Extensive laboratory tests using this system have confirmed the ability to operate in the non-equilibrium mode (with energy levels in the range of 0.6-0.7 eV/molecule) as shown in the following examples, however the typical small size of these systems, together with the limited power supplies in use, are a serious impediment to their commercial, large-scale use.

By means of the following examples the non-equilibrium plasma characteristics have been confirmed using the supersonic fixture with the nozzle mounted at the input end of the reactor. Also presented is the case of the same reactor operated without the supersonic nozzle shown in FIG. 3B. Although high methane conversion rates are possible in both configurations (with and without the nozzle), there is a 10-fold increase in gas throughput with only a 43% increase in microwave power when using the supersonic nozzle. More importantly, the supersonic operation enables the process to occur at much lower input energy (eV/molecule) and with correspondingly less heat generation.

### Example 1—Supersonic Nozzle

| | |
|---|---|
| N2 | 80 SLPM |
| CO2 | 10 SLPM |
| CH4 | 1 SLPM |

Power = 4000 watts
Input Specific Energy = 0.614 eV/molecule
Methane conversion 100%

### Example 2—Supersonic Nozzle

| | |
|---|---|
| N2 | 80 SLPM |
| CO2 | 10 SLPM |
| CH4 | 4 SLPM |

Power = 4000 watts
Input Specific Energy = 0.594 eV/molecule
Methane conversion 60%

### Example 3—Supersonic Nozzle

| | |
|---|---|
| N2 | 80 SLPM |
| CO2 | 0 SLPM |
| CH4 | 1 SLPM |

Power = 4000 watts
Input Specific Energy = 0.704 eV/molecule
Methane conversion 100%

### Example 4—No Supersonic Nozzle

| | |
|---|---|
| N2 | 0 SLPM |
| CO2 | 5.45 SLPM |
| CH4 | 4.55 SLPM |

Power = 2800 watts
Input Specific Energy = 3.91 eV/molecule
Methane conversion 100%

All the above embodiments have been disclosed at various times in the open literature, all with the noted limitations involving the use of a secondary (vortex) gas. Furthermore, even in the case where the secondary gas is a reagent gas, because of the relatively high gas flows required to maintain an effective vortex effect, the large volume and location of the secondary gas around the reaction (plasma) zone leads to reduced gas conversion since much of the gas bypasses the active plasma region, a condition known as “gas slip”, in which case the gas conversion is typically not greater than 60% at the highest (rated) gas flows.

There remains, therefore, a need to be able to couple the largest microwave power sources (hundreds of kW) with sufficiently large reactors to achieve industrial-scale capacity while preserving the energy advantages of non-equilibrium operation and simultaneously achieving complete or nearly complete gas conversion.

By means of the present invention, this limitation in gas conversion has been overcome while maintaining all the advantages of supersonic gas expansion, and without the introduction of any secondary (non-reagent) gas. This improvement is based on the introduction of a reverse vortex gas flow in the post-nozzle plasma zone. The gas used to form the reverse vortex is the same composition as the plasma gas, hence eliminating the need for subsequent gas removal. The reverse vortex serves the purpose of providing a thermal barrier between the plasma and the reactor vessel wall, providing a pressure “containment” barrier for the plasma and ensuring that all the gas in the system is constrained to pass directly through the high-energy central region along the reactor axis as illustrated in FIG. 1.

### BRIEF DESCRIPTION OF THE DRAWINGS

FIG. 1 is a cross sectional elevation view of an embodiment of the microwave plasma self-catalytic reactor of the present invention.

FIG. 2A is partial cross section elevation view of a waveguide coaxial transformer of the system of the present invention. FIG. 2B is a representation of a vortex produced in the transformer of FIG. 2A.

FIG. 3 is simplified perspective view of an embodiment of a resonant cavity of the system of the present invention.

FIG. 4A is a perspective view of a single-cavity embodiment of a reactor of the present invention wherein two separate microwave sources are connected to the reactor. FIG. 4B is a cross sectional plan view of the reactor of FIG. 4A.

FIG. 5 is a simplified representation of an embodiment of a waveguide conduit of the present invention.

FIG. 6A is a graph illustrating the gas velocity profile in a nozzle of the present invention. FIG. 6B is a graph illustrating the gas pressure profile of the nozzle.

FIG. 7A is a simplified side view of an embodiment of the invention including a small-aperture interposed immediately at the downstream end of the plasma excitation zone. FIG. 7B is a simplified plan view o of an embodiment of the invention including the small-aperture interposed immediately at the upstream end of the plasma excitation zone.

FIG. 8 is a simplified side view of an embodiment of the reactor of the present invention showing microwave energy introduced into a cylindrical metallic cavity by means of one or more waveguide conduits such that the fundamental waveguide mode in the waveguide(s) is transformed into the TE11 mode within the cavity. Plasma gas products are then directed into a fluidized catalyst bed reactor.

FIG. 9 is a simplified side view of the reactor of FIG. 8 showing the case in which the gas connection between the plasma reactor and the catalyst fluidized bed reactor is a supersonic gas expansion nozzle.

FIG. 10 is a simplified side view representing an embodiment of the present invention wherein a plasma is formed within a separate microwave-transparent gas-containment vessel within the metallic reactor vessel.

FIG. 11 is a simplified side view representing an embodiment of the reactor system of the present invention wherein microwave energy is used to directly heat a catalyst material within the microwave reactor vessel.

FIG. 12A is simplified cross sectional side view representation of a planar microwave source for use as part of the present invention. FIG. 12B is a simplified cross sectional top view of a coaxial multi-conductor microwave source for use as part of the present invention.

FIG. 13 is a simplified side view of a waveguide fitted with two or more bend sections so as to allow a microwave-transparent second vessel containing catalyst material to pass through said waveguide to form a packed-bed reactor.

FIG. 14 is a simplified representation of an embodiment of the invention showing a waveguide sharing a common wall boundary with a second vessel containing catalyst material.

FIG. 15A is a simplified elevation view of a catalyst vessel of the present invention formed into a number of loops connected in alternating fashion to wave guides by apertures. FIG. 15B is a simplified elevation view of a catalyst vessel of the present invention formed into a number of straight sections connected in alternating fashion to wave guides by apertures.

FIG. 16 is simplified block diagram presenting primary steps of a method of the present invention enabled by one or more of the systems described herein.

FIG. 17 is a simplified representation of primary elements and their interfaces in an exemplar system of the present invention.

### DETAILED DESCRIPTION OF THE INVENTION

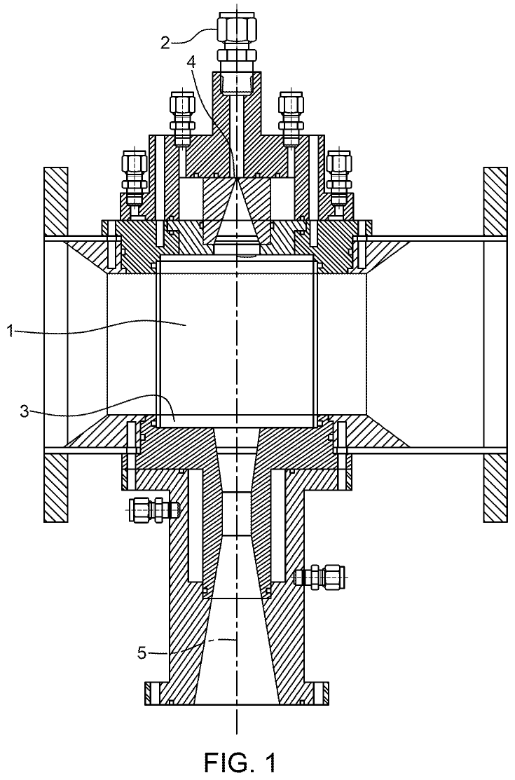

With reference to FIG. 1, gas is introduced to the reactor (1) by means of an axial feed (2) as well as by means of one or more tangential feeds (3) located around the bottom periphery of the reactor vessel. The purpose of the tangential feed(s) is to introduce a reverse vortex flow in the reactor by which the vortex gas proceeds upward around the periphery of the reactor vessel, reflects from the top of the vessel and proceeds downward in a substantially radially confined manner. The gas entering through the inlet (2) passes through the supersonic nozzle (4), enters the plasma reaction zone within the reactor vessel (1) and exits via a diffuser nozzle (5) designed to control the gas velocity to subsonic speed and to pressure balance the flow to near-atmospheric level to avoid the generation of shock waves. The principal advantages of the reverse vortex configuration as shown include the ability to use reagent input gas as a cooling agent against the reactor walls (before being redirected axially in the central plasma zone) as well as supporting the use of larger-diameter reactor vessels and hence higher gas volumetric flow.

The other fittings shown in FIG. 1 are for the purpose of allowing the flow of water into specially configured channels to cool the reactor system.

It will be immediately recognized by one who is knowledgeable in microwave science and engineering that the reactor system described generically in FIG. 1 is dependent upon configuring the reactor so that the gas (and plasma) containment system must effectively pass through the microwave containment system, and that the said gas containment system must be comprised of material(s) that are essentially transparent to microwave energy of the frequency being used to support the plasma. This limits the material(s) of reactor vessel construction to certain high-purity quartz or similar materials. In some instances, the use of such materials may be prohibited due to pressure limitations, i.e. the quartz material may be unable to withstand the internal reactor vessel pressure and may become susceptible to fracture or breakage, either of which would lead to an immediate failure of the plasma system.

Recognizing the potential limitations of reactor systems generically similar to that illustrated in FIG. 1 and described above, it is desirable in some instances to use a reactor vessel which is all metal and which contains no breakable parts.

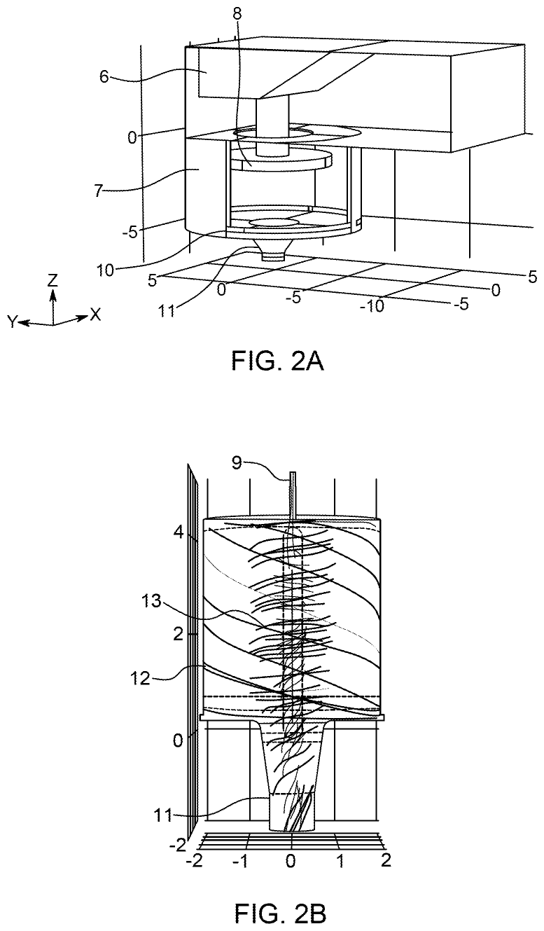

With reference to FIG. 2A, we illustrate another embodiment of the present invention in which a waveguide coaxial transformer (6) couples microwave energy into a resonant cylindrical cavity (7). The enlarged electrode disc (8) serves to widen the electromagnetic energy distribution within the cavity (7) where the microwave plasma is supported. Gas is introduced by means of an axial feed (9), which may include a supersonic nozzle of the general type described earlier, through the transformer and electrode disc and by means of tangentially mounted inlets (10) at the bottom periphery of the cavity (7), the purpose of which is to induce a reverse vortex gas flow within the cavity (7), and exits via the central discharge outlet (11). The vortex flows upward (12) around the reactor shell as illustrated in the FIG. 2B and downward in the central axial region (13) after being reflected from the electrode disc (8).

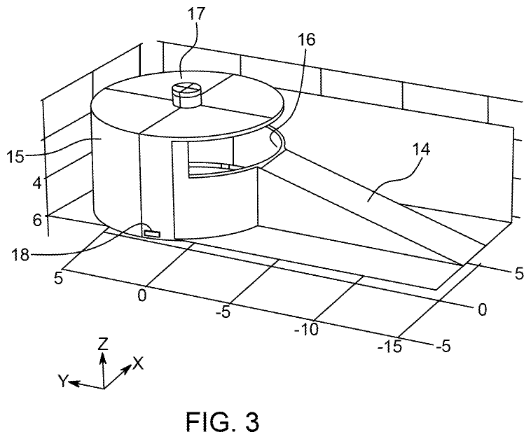

With reference to FIG. 3 we illustrate a further embodiment of the present invention in which a waveguide transformer (14) couples energy into a resonant cylindrical cavity (15) by means of an annular aperture (16) which may be located at either the top or bottom of the reactor cavity. Gas enters the cavity (15) by means of an axial feed (17), which may include a supersonic nozzle of the general type described earlier, and by means of tangentially mounted inlets (18) at the bottom periphery of the cavity (15), the purpose of the said tangential feeds being to induce a reverse vortex gas flow within the cavity (15). The microwave plasma is contained within the reactor cavity (15). Gas then exits via a central axial outlet at the bottom of the cavity (15).

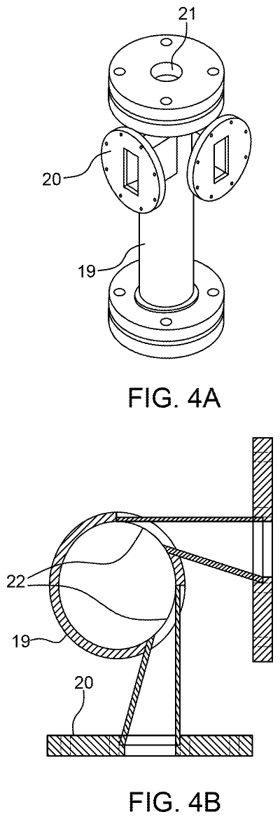

With reference to FIGS. 4A and 4B, we illustrate another embodiment of this present invention wherein a single reactor is fed by two or more waveguide sources, thus increasing the power capacity of the reactor system above that available using only a single microwave source. This reactor consists of a cylindrical reactor body (19) and two waveguide feeds (20). Gas enters the reactor by means of an axial feed (21), which may include a supersonic nozzle of the general type described earlier, as well as via the waveguides (20). The waveguide feeds are mounted tangentially with respect to the reactor body and the sectoral aperture (22) dimensions are used to match the waveguide impedance to that of the reactor. The microwave plasma is produced within the reactor body (19). One or more additional gas inlets may be used to introduce a reverse vortex gas flow within the reactor for the purpose of controlling the gas flow as described above.

The synergy between plasmas and catalysts is based on the fundamental principles of operation of each of these components. Catalyst operation requires the preparation of specific activation sites on the surface of the catalyst material; at these sites, the work function for a particular chemical operation is reduced, thus allowing the chemical operation to proceed with a reduced input energy or an equivalent reduction in operating temperature. The preparation of the catalyst activation sites may be carried out by several means, often involving the deposition of specific metallic molecular groups which are “tuned” to target molecules or ions in the process stream. Since catalyst activity is a surface phenomenon, catalyst effectiveness increases with the surface area exposed to the process stream and is negatively affected by any operation which occludes, blocks, abrades or otherwise neutralizes the catalyst material coating.

Plasma streams are highly chemically active due to their energetic species composition and are often self-catalytic, i.e. they can promote certain chemical operations at lower energy input than similar operations using non-plasma techniques. The synergy between plasmas and catalytic materials is at least partially intuitive since both are fundamentally defined by an energetic, charged, chemically active material composition.

Non-thermal plasmas produce ions, radicals and electronically excited species with internal energies that are often higher than the activation energies for thermal catalysis; these species can enhance plasma volume reactions. This can be attributed to the high threshold energies required to generate these species through electron collision processes. For ions and radicals, threshold energies of 5-20 eV are typically required and for electronically excited species, threshold energies are in the range of 1-10 eV. Vibrationally excited species are produced with the lowest threshold energies of 0.1-1 eV, hence the internal energies are too low to facilitate plasma volume reactions. However, activation energies for reactions involving vibrational species can be lowered when adsorbed to a catalyst surface; consequently, the vibrational state can be a significant contributor to the acceleration of catalysis. In addition, the energy required for surface adsorption of radical species may be lower than for adsorption of ground state gas molecules.

Several studies have revealed the synergistic effects of the plasma-catalyst combination, however these studies have focused on the use of very small-scale applicators (reactors), usually involving dielectric barrier discharge (DBD) plasmas which, for several reasons, cannot achieve economic large-scale operation. Although not capable of commercial scale of operation, these reactors have successfully demonstrated plasma-catalyst synergistic effects in dry reforming of methane and carbon dioxide over Cu—Ni/γ-Al₂O₃ where the result for the plasma-catalytic reaction was greater than the sum of the catalyst only and plasma only results. Hydrogen and carbon monoxide selectivities were also enhanced by the use of plasma catalysis. Synergistic effects have also been observed for other reactions including steam methane reforming of biogas over Cu—Ni/γ-Al₂O₃ catalysts, hydrogenation of carbon dioxide and destruction of toluene, benzene and hydrofluorocarbons.

By means of the present invention, these and other process reactions may be carried out at industrial scale and at minimum energy cost. The realization of this operation is made possible, as herein disclosed, by the introduction of a large-scale microwave plasma source in combination with an inhomogeneous catalyst structure.

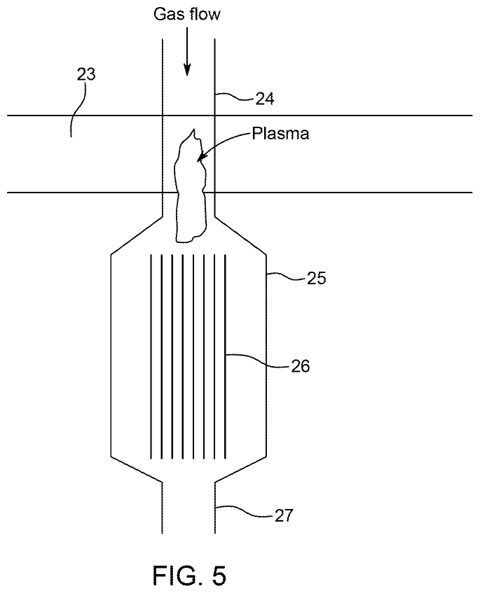

FIG. 5 illustrates one embodiment of the present invention wherein microwave energy contained in a waveguide conduit (23) excites a plasma in a transversely-oriented conduit (24), said conduit (24) within the boundary of the waveguide structure (23) being essentially transparent to the microwave frequency being used (i.e. the dielectric properties of the conduit (24) are such that very little of the microwave energy is lost through conversion into heat within the conduit material) such that microwave energy passes unrestricted into the gas contained within the conduit (24). The plasma so formed extends beyond the boundary of the waveguide, while being fully contained in the conduit (24), and enters a metallic cavity (25) in which is mounted an array of catalytic material (26). The inhomogeneous catalyst array (26), comprising catalyst materials attached to a supporting framework, is configured to provide maximum surface area exposure of the catalyst to the plasma while also providing as little obstruction as possible to the flow of gas (plasma) through the system. One such catalyst configuration may be a monolithic arrangement of closely-spaced parallel cylinders whose axes are parallel to the longitudinal axis of the vessel (25). In another configuration, the catalyst may be supported within a highly-porous solid medium such as a zeolite. In another configuration, the catalyst may be supported on a network of small-diameter wires forming a loosely-packed batting.

Within the cavity (25) the chemical reaction is completed to the desired extent and the product gas exits via an exhaust duct (27).

Although the waveguide configuration illustrated in FIG. 5 (but without the catalyst reaction chamber) has been widely used for many years in laboratory and small-scale applications, it has now been made possible, by means of certain modifications described herein, to operate the system at much higher process rates while ensuring that the plasma so-formed is truly operating in the non-equilibrium mode and hence at minimum energy cost. This is accomplished by taking advantage of the properties of supersonic gas expansion using a nozzle device which constricts the gas flow, causing it to reach sonic velocity (Mach 1) in the nozzle throat, and thereafter to expand in a diverging section designed to increase gas velocity above Mach 1 and to prevent thermal re-generation by adjusting the diverging nozzle angle to ensure critical heat transfer, i.e. plasma heat is transferred to the nozzle walls rather than being allowed to increase the gas temperature, thus reducing the gas flow to sub-sonic velocity.

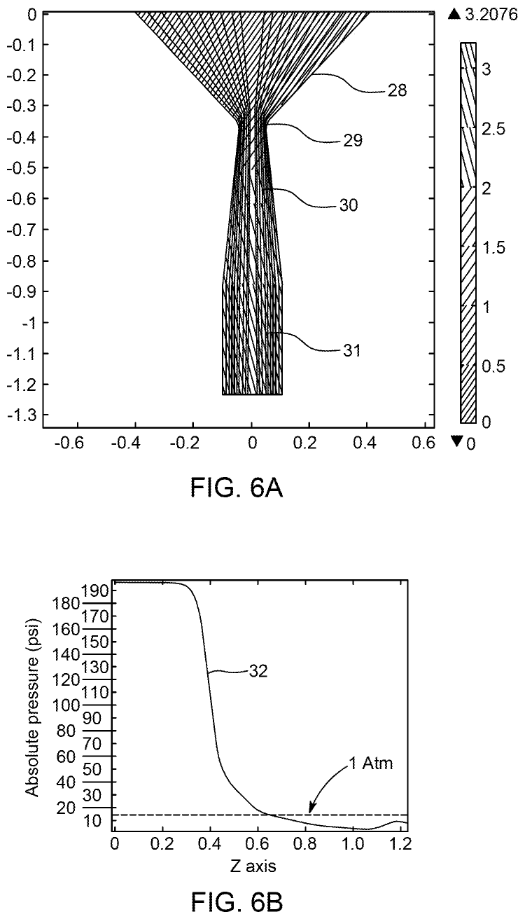

With reference to FIGS. 6A and 6B, a gas stream (28) is directed through a convergent pipe to an aperture (29) where the gas velocity reaches the speed of sound (Mach 1). The gas thereafter enters a divergent nozzle (30) in which the gas velocity increases above Mach 1 by a process known as supersonic expansion. This supersonic zone extends some distance down the nozzle to a point (31) where it becomes sub-sonic. Within the supersonic zone, the pressure is significantly reduced (32) (FIG. 6B) and the gas temperature also reduces rapidly.

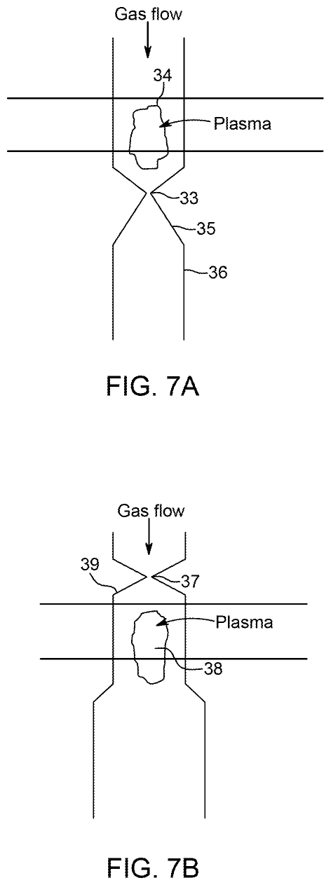

With reference to FIG. 7A, a small-diameter aperture (33) has been interposed immediately at the downstream end of the plasma excitation zone (34) such that the gas passing through said aperture reaches supersonic speed and thereafter expands in a nozzle (35) before entering the catalyst zone (36). The benefits of the supersonic nozzle expansion include an extremely rapid quenching of plasma species formation (thus preventing unwanted reverse reactions) and a transformation of most of the molecular energy into the vibrational mode (thus ensuring minimum heat generation).

For gas volume rates of the order of 100 SLPM, the required aperture diameter may not exceed 2 mm in order to ensure supersonic operation. Higher gas flow rates will allow a larger-diameter aperture to be used.

In another embodiment shown in FIG. 7B, the small-diameter aperture (37) is interposed at the upstream end of the plasma zone (38), the advantage being that the low-pressure region created in the supersonic nozzle (39) is beneficial for the generation of the plasma and for optimization of vibrational excitation of the gas molecules.

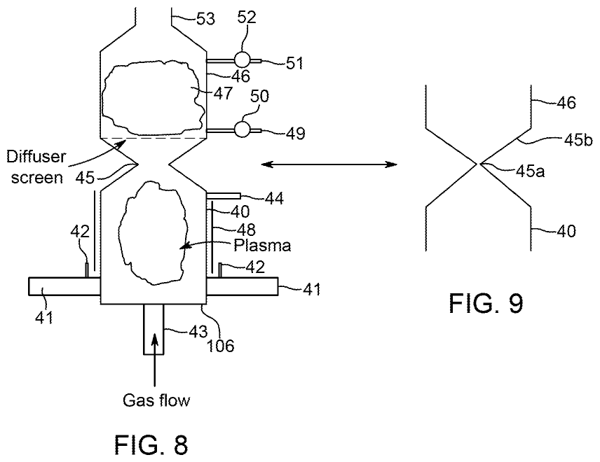

FIG. 8 illustrates another embodiment of the present invention wherein microwave energy is introduced into a cylindrical metallic cavity (40) by means of one or more waveguide conduits (41) such that the fundamental waveguide mode in the waveguide(s) (41) is transformed into the TE11 mode within the cavity (40). The benefit of this TE11 mode configuration is that the energy distribution within the cavity (40) is maximized along the longitudinal axis and furthermore maximized by the placement of a metallic end plate (106) to the cavity. A plasma is thus formed and sustained within the cavity (40). Process gas is introduced either through fixture(s) (42) in the waveguide(s) or by means of other fittings (43), (44) to the cavity such that there is a dominant vortex flow pattern to the gas within the cavity. The benefit of using the vortex flow is that some or essentially all of the process gas entering the cavity can be constrained to flow in the vicinity of the maximum microwave power density (expressed in terms of microwave power per unit volume), thus enhancing plasma formation and reactivity. An inherent advantage of this embodiment of the plasma reactor is that it is all-metal, containing no fragile or otherwise sensitive materials that may be subject to deformation, occlusion or breakage.

The plasma so formed within the cavity (40) exits via an exhaust conduit (45) and enters a second cavity (46) containing catalyst materials (47) in the form, for example, of powder, pellets or short, hollow cylinders but not limiting the catalyst structure to these forms. The second cavity (46) is disposed to operate as a fluidized bed (specifically a bubbling fluidized bed) in which the catalyst materials (47) are suspended and continuously intermixed in an expanded bed supported by the plasma gas flow from the reactor cavity (40). The design of fluidized beds is well known such that the size of the second cavity (46), the size and shape of the catalyst “particles”, the depth of the fluidized bed (47) and the gas characteristics can be used to produce the desired fluidized bed operating characteristics. The dimensions of the fluidized bed cavity (46) are further constrained to ensure that the cavity is below the cutoff of the microwave frequency being used, thus ensuring that the microwave energy is fully contained within the reactor cavity (40). The gas stream thereafter exits from the fluidized bed chamber (46) through an exhaust conduit (53) and may be further processed, cleaned or otherwise disposed.

The characteristics of the fluidized bed (47) are such that the individual catalyst “particles” are continuously circulated throughout the bed, with the fluidizing gas passing through the spaces between the “particles” such that the processing occurring in the bed, being between the process gas components and the catalyst materials, achieves an overall steady-state condition, and although the bed itself may not have completely uniform characteristics (such as temperature), the gas product passing through it, by virtue of the many possible random paths through the bed, will achieve a steady state condition. In order to assist in minimizing heat loss from the fluidized bed, an external insulation (48) may be added to the vessel.

Furthermore, by the nature of the disclosed system including the fluidized bed, the catalyst material may be periodically exchanged by opening a discharge pipe (49) through a gas interlock valve (50), and similarly adding new catalyst material through an inlet pipe (51) through a gas interlock valve (52).

FIG. 9 (with FIG. 8) illustrates another embodiment of the present invention wherein microwave energy is introduced into a cylindrical metallic cavity (40) by means of one or more waveguide conduits (41) such that the fundamental waveguide mode in the waveguide(s) (41) is transformed into the TE11 mode within the cavity (40). The benefit of this TE11 mode configuration is that the energy distribution within the cavity (40) is maximized along the longitudinal axis and furthermore maximized by the metallic end plate (106) to the cavity (40). A plasma is thus formed and sustained within the cavity (40). Process gas is introduced either through fixture(s) (42) in the waveguide(s) or by means of other fittings (43), (44) to the cavity such that there is a dominant vortex flow pattern to the gas within the cavity. The benefit of using the vortex flow is that some or essentially all of the process gas entering the cavity can be constrained to flow in the vicinity of the maximum microwave power density, thus enhancing plasma formation and reactivity. An inherent advantage of this embodiment of the plasma reactor is that it is all-metal, containing no fragile or otherwise sensitive materials that may be subject to deformation, occlusion or breakage.

The plasma so formed within the cavity (40) exits via a small-diameter aperture (45a) such that the gas velocity becomes supersonic; the gas is thereafter expanded in a nozzle (45b) before entering a second cavity (46) containing catalyst materials (47) in the form of powder, pellets or short, hollow cylinders. The second cavity (46) is closely affixed to the reactor cavity (40) such that the transit time of gas (plasma) exiting the supersonic nozzle (45b) is minimized, preferable to less than 1 millisecond. For example, at approximately Mach 2, the gas travels about 0.5 m in 1 millisecond, meaning that the second reactor must be located within 0.5 m from the first reactor (40). Once in the second reactor (46), the gas velocity rapidly decreases. The benefits of the supersonic nozzle include prevention of unwanted reverse reactions and isolation of pressure fluctuations in the second cavity (46) from the plasma environment in the first cavity (40). The second cavity (46) is disposed to operate as a fluidized bed (specifically a bubbling fluidized bed) in which the catalyst materials (47) are suspended and continuously intermixed in an expanded bed supported by the plasma gas flow from the reactor cavity (40). The design of fluidized beds is well known such that the size of the second cavity (46), the size and shape of the catalyst “particles”, the depth of the fluidized bed (47) and the gas characteristics can be used to produce the desired fluidized bed operating characteristics. The dimensions of the fluidized bed cavity (46) are further constrained to ensure that the cavity is below the cutoff of the microwave frequency being used, thus ensuring that the microwave energy is fully contained within the reactor cavity (40). The gas stream thereafter exits from the fluidized bed chamber (46) through an exhaust conduit (53).

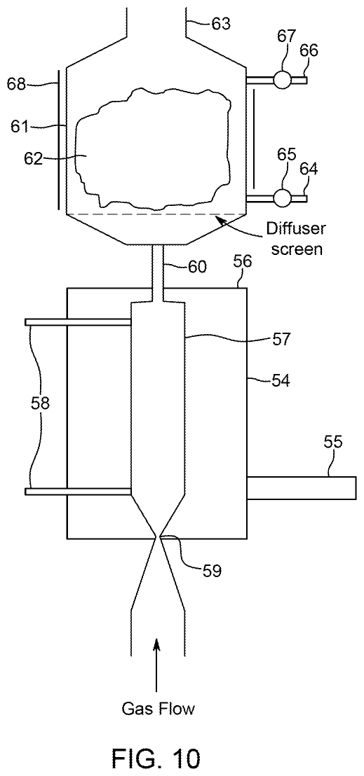

FIG. 10, illustrates another embodiment of the present invention wherein microwave energy is introduced into a cylindrical metallic cavity (54) by means of one or more waveguide conduits (55) such that the fundamental waveguide mode in the waveguide(s) (55) is transformed into the TE11 mode within the cavity (54). The benefit of this TE11 mode configuration is that the energy distribution within the cavity (54) is maximized along the longitudinal axis and furthermore maximized by the placement of a metallic end-piece (56) to the cavity. A second cavity (57), being essentially transparent to microwave energy, is introduced into the first cavity (54). A plasma is thus formed and sustained within the second cavity (57). Process gas is introduced into the cavity (57) through tangentially mounted inlets (58) and by means of a small-diameter nozzle (59) such that there is a dominant vortex flow pattern to the gas within the second cavity (57) as well as a supersonic velocity component due to the effect of the small-diameter nozzle (59). The benefit of using the vortex flow is that some or essentially all of the process gas entering the cavity can be constrained to flow in the vicinity of the maximum microwave power density, thus enhancing plasma formation and gas reactions. As well, the vortex flow (particularly when a reverse vortex flow is used) acts to insulate the vessel (57) from the plasma heat. The advantage of using the second cavity (57) is that it constrains the gas flow to a smaller diameter cross section, thus enhancing the vortex flow pattern and reducing the transit time of the gas passing through the plasma region. Furthermore, the use of the second vessel (57) maintains the plasma from contacting the metallic walls of the first vessel (54), thus preventing heating of the vessel. The advantage of using the waveguide mode conversion feed arrangement is that multiple waveguide generators and feeds may be connected to the same reactor, effectively increasing the processing capacity of the unit. For example, using a microwave frequency of 915 MHz, the reactor vessel (54) is at least approximately 10 inches in diameter and the second vessel (57) may be up to 4 inches or 6 inches in diameter such that the total gas flow and power input are significantly higher than possible using other reactor configurations.

The plasma so formed within the cavity (57) exits via a connecting conduit (60) before entering a second cavity (61) containing catalyst materials (62), for example in the form of powder, pellets or short, hollow cylinders. The second cavity (61) is closely affixed to the reactor cavity (54) such that the transit time of gas (plasma) exiting the first reactor (54) is minimized. The second cavity (61) is disposed to operate as a fluidized bed of catalyst material (62) (specifically a bubbling fluidized bed) in which the catalyst materials (62) are suspended and continuously intermixed in an expanded bed supported by the plasma gas flow from the reactor cavity (54). The design of fluidized beds is well known such that the size of the second cavity (61), the size and shape of the catalyst “particles”, the depth of the fluidized bed (62) and the gas characteristics can be used to produce the desired fluidized bed operating characteristics. The dimensions of the fluidized bed cavity (61) are further constrained to ensure that the cavity is below the cutoff of the microwave frequency being used, thus ensuring that the microwave energy is fully contained within the reactor cavity (54). The gas stream thereafter exits from the fluidized bed chamber (61) through an exhaust conduit (63).

The characteristics of the fluidized bed (62) are such that the individual catalyst “particles” are continuously circulated throughout the bed, with the fluidizing gas passing through the spaces between the “particles” such that the processing occurring in the bed, being between the process gas components and the catalyst materials, achieves an overall steady-state condition, and although the bed itself may not have completely uniform characteristics (such as temperature), the gas product passing through it, by virtue of the many possible random paths through the bed, will achieve a steady state condition.

Furthermore, by the nature of the disclosed system including the fluidized bed, the catalyst material may be periodically exchanged by opening a discharge pipe (64) through a gas interlock valve (65) and similarly adding new catalyst material through an inlet pipe (66) through a gas interlock valve (67).

In order to assist in minimizing heat loss from the fluidized bed, an external insulation (68) may be added to the vessel.

The operation of catalyst materials is based on the ability to deposit energy (or energized materials) in such a way as to interact with a process stream whereby the deposited energy allows chemical reactions to occur with less input energy and/or in a preferential manner so as to favor certain chemical reactions.

Microwave energy is able to interact directly with most materials either through electronic stimulation or through thermal excitation by means of dielectric heating. It has been shown that catalyst materials, when heated directly by microwave energy, demonstrate enhanced catalytic properties for many reactions. This enhancement occurs without the formation of a plasma. Although this effect has been demonstrated only at very small-scale, by means of the present invention the effect may be realized at much larger commercial scales of operation.

One fundamental limitation in the combined use of microwave energy and catalysts is due firstly to the characteristic non-uniform microwave energy distribution throughout the dielectric catalyst medium, and secondly due to the inherent non-uniform microwave field distribution within all microwave reactor systems.

As disclosed herein, several techniques may be employed to counter the effects of these non-uniformities, with the objective of producing a relatively uniform bulk heat distribution throughout the catalyst material. An important distinction here in reference to the bulk heat distribution is the recognition that, on a micro-scale, the temperature distribution within the catalyst material may be highly non-uniform due to the interaction of microwave energy with the catalyst metallic deposition sites, resulting in relatively higher temperatures at these sites.

Methodologies designed to mitigate the effects of these non-uniformities described herein may include, without limitation, the following:
1. Moving the catalyst material within the reactor microwave field, thus randomizing the exposure of individual catalyst particles to microwaves, and also promoting conductive heat transfer throughout the catalyst material;
2. Making use of multiple microwave energy injection points throughout the catalyst, particularly along the direction of microwave propagation;
3. Introducing multiple microwave feed systems which inject energy into the catalyst material at multiple locations and from opposing directions, particularly with respect to the directions of microwave propagation;
4. Introducing a secondary containment system within the microwave reactor in such a way as to place the catalyst material in an advantageous position within the reactor microwave field, and to constrain the reagent gas to flow through said advantageous region, particularly in both cases to avoid placing catalyst and reagent gas(es) in regions of low microwave energy density within the reactor;
5. Modulating the microwave absorption properties of the catalyst material(s), either through the use of different dielectric host materials (different dielectric permitivities) or by the introduction of “promoter” admixtures or coatings with or on the catalyst material(s) respectively, said “promoter” materials consisting typically, but not exclusively, of metal oxides which remain inert with respect to the chemical reactions within the reactor vessel.
6. Removing and regenerating catalyst material, either in a batch or continuous manner, using essentially the same apparatus as disclosed herein, and thereafter reintroducing said regenerated catalyst into the process system, the purpose being to mitigate the decrease in catalyst efficacy due to pollutant accumulation, said accumulation commonly occurring at the inlet end of the catalyst structure and thereby introducing a non-uniformity in catalyst performance along the reactor in the direction of gas flow.

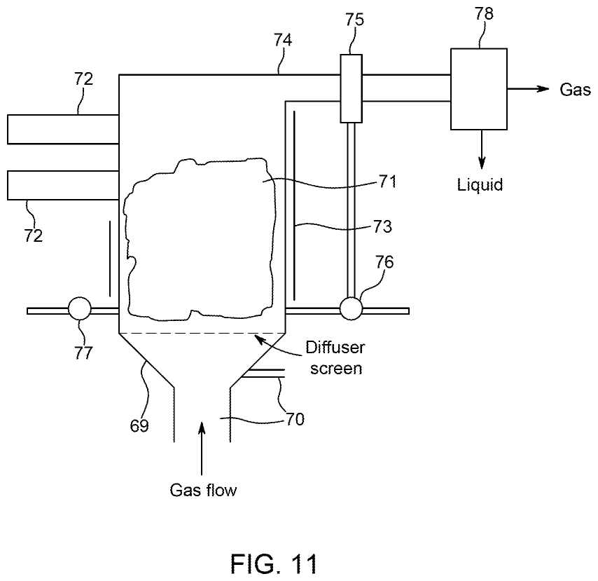

FIG. 11 illustrates one embodiment of the present invention according to the methodology above whereby the synergistic effects of microwave energy and catalyst materials may be realized. Gas or gas products are introduced into a reactor vessel (69) via an inlet duct (70), which may include the product stream from a previous process stage as described heretofore. The reactor vessel (69) functions as a containment vessel, either single or multi-mode, for microwave energy as well as for the gas stream and the catalyst materials to be used in the process.

It is recognized that some chemical reactions which one may wish to carry out using this invention require elevated pressures (compared to atmospheric pressure) within the reactor; in such cases, it may be advantageous to interpose a pump or compressor at the inlet (70).

In one embodiment as shown in FIG. 11 the reactor vessel may be a cylindrical body configured to operate as a bubbling fluidized bed in which the catalytic materials (71) may be, for example but not limited to, granular powder, pellets or short hollow cylinders. Microwave energy is directed into the reactor vessel by means of one or more waveguide(s) (72) and the reactor vessel is designed to be above the cutoff frequency for at least the dominant mode at the microwave frequency being used. More than one waveguide feed may be employed and more than one microwave frequency may be used. The reactor vessel (69) may be insulated (73) to prevent heat loss. Gas products exit the reactor vessel via a duct (74) and may pass through a cyclone filter (75) or similar device to capture solid particulate that escapes from the fluidized bed, said particulate being returned to the bed through a gas interlock valve (76). Catalytic material may be removed from and returned to the fluidized bed by means of a separate gas interlock valve system (77). Gas products passing through the cyclone filter are condensed in a condenser (78), from which liquid and gas products may be collected.

It may be beneficial in some operations to introduce additional gas material(s) into the reactor vessel (69) by means of separate inlet duct(s) (70).

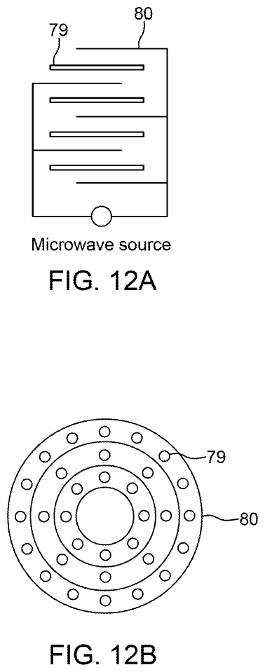

As an example of another embodiment (FIGS. 12A and 12B) of the present invention, the reactor vessel may take the form of an interleaved arrangement of small-diameter catalyst tubes or channels (79) with electrical conductors (80) to form cylindrical (FIG. 12B) or planar (FIG. 12A) or possibly other interleaved arrangements.

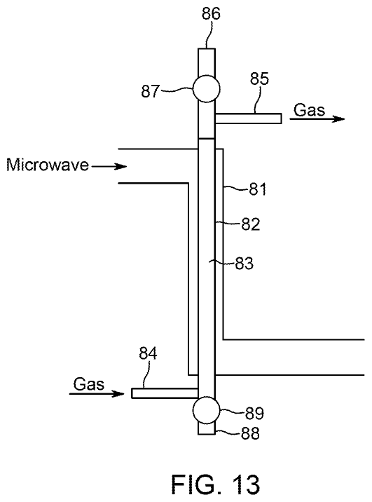

In another embodiment (FIG. 13) of the present invention according to the methodology above, a waveguide (81) containing microwave energy is fitted with two or more bend sections so as to allow a microwave-transparent second vessel (82) containing catalyst material (83) to pass through said waveguide to form a packed-bed reactor. Process gas is introduced into the second vessel by means of an inlet conduit (84), passes through the catalyst bed and exits by means of a second outlet conduit (85). The catalyst material may be maintained static in the bed or may be exchanged by introducing new material at inlet pipe (86) through an inlet gas valve (87) and discharging the material at discharge pipe (88) through a gas valve (89). In the case where the reactor vessel is vertically oriented, the catalyst inlet pipe is usually positioned above the discharge pipe so that the catalyst material may flow through the reactor under the force of gravity, with the process gas stream flowing counter-current, i.e. from bottom to top.

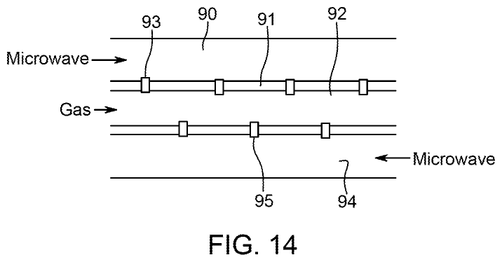

In another embodiment (FIG. 14) of the present invention according to the methodology above, a waveguide (90) containing microwave energy shares a common wall boundary with a second vessel (91) containing catalyst material (92). The common wall boundary contains a series of periodically spaced apertures (93) which allow the passage of microwave energy into the catalyst region but which prevent the passage of either catalyst material or gas into the waveguide. The size and geometry of the second vessel (91) are such that it is capable of supporting the propagation of microwave energy at the frequency being used, in which case the apertures coupling the waveguide to the second vessel cause microwave energy to be dissipated as heat within the catalyst material in the regions near the apertures. Since it may be expected that the coupling of microwave energy from the waveguide will result in a lessening of the microwave field (and hence the local heating effects) in the direction of microwave propagation, a second waveguide (94) and series of apertures (95) may be introduced in which the direction of microwave propagation with respect to the first waveguide is reversed, thus compensating for the power attenuation along the reactor.

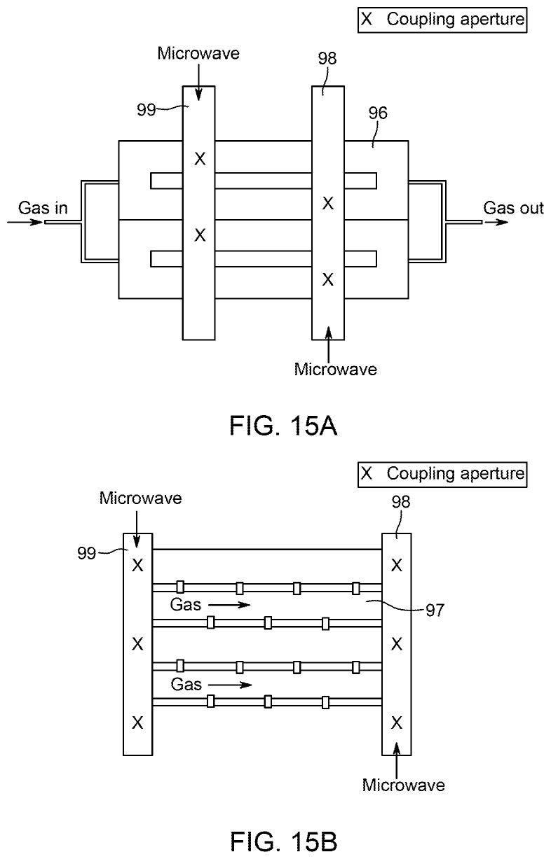

In a further development of this geometry as shown in FIGS. 15A and 15B, the catalyst vessels may be formed into a number of loops (96) (FIG. 15A) or straight sections (97) (FIG. 15B) and connected in an alternating fashion to two waveguides (98), (99) by means of apertures which permit the passage of microwave energy while preventing the passing of catalyst material or gas. An advantage of the present configurations is that both the waveguide and catalyst conduits may be constructed in modular fashion using simple pressed-metal and welding techniques and the catalyst vessels so formed are amenable to mounting heterogeneous wire-supported catalyst structures. By combining several such modules, one may achieve high process volumes and take advantage of large industrial microwave sources. The microwave generators may be either single high-power units or an array of low-power units appropriately connected to the waveguides. A further advantage of the present configuration is that one or more processes may be operated at the same time by simply employing different catalyst materials at different stages of the system.

In another embodiment of the present invention according to the methodology above, the catalyst materials may be arranged in a stationary manner within the microwave reactor either in the form of concentric cylindrical tubes (each having different dielectric absorption properties) or arranged as stacked “pucks” (each having different dielectric absorption properties), said pucks comprising a catalyst material which is either mixed with or coated by a separate “promoter” material designed to selectively absorb microwave energy.

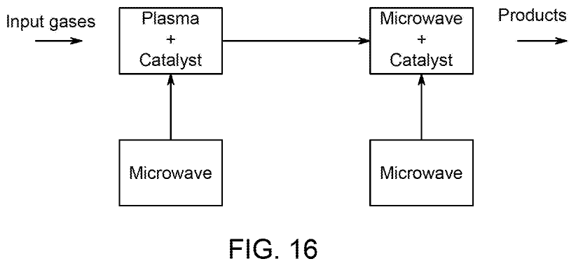

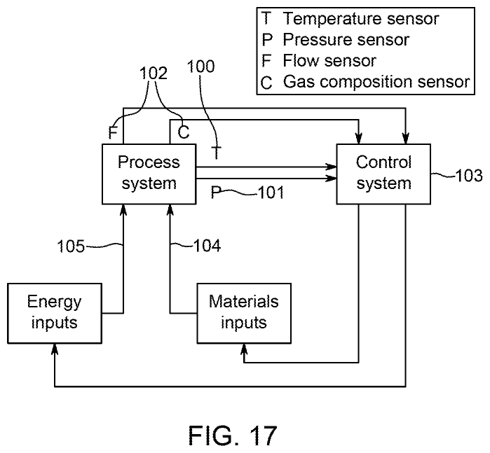

The processing system shown in FIG. 16 may be operated in a connected fashion, as shown, or as two independent process stages. The process stages may be separately controlled (FIG. 17) to optimize desired conditions, for example to maximize the production of a desired end product, to optimize the ratios of product gas mixtures, to minimize energy costs within some or all of the process operations, etc. To this end, the system may be equipped with instruments that monitor temperatures (100), pressures (101), gas flows and compositions (102), etc. The information gathered by means of this instrumentation may be used as input to a control system (103), which may be computer controlled, to adjust the material (104) and energy (105) inputs to the system. For example, the temperature within a reactor vessel may be adjusted by means of adjusting the input microwave power and/or by adjusting the flow rates of the input gases. By means of such a control system, the overall process may be regulated to operate within a specified range of conditions.

The invention claimed is:

1. A system for processing gaseous materials through the use of microwave non-equilibrium plasmas, said system comprising
a) a microwave source connected to a waveguide,
b) a means of coupling said microwave energy from the waveguide to a vessel acting as a gas containment reactor vessel in which the plasma is generated and maintained,
c) a first means of directing reagent gas into the said reactor vessel by means of supersonic nozzle gas expansion,
d) a second means of directing reagent gas tangentially into the said reactor vessel in such a way as to generate a vortex flow which first is directed counter to the supersonic flow direction, is reflected from the top of the said reactor vessel and thereafter is directed in the same direction as the supersonic flow, and
e) a means of allowing the post-plasma gas products stream pressure to be adjusted suitably for further processing or discharge.

2. The system according to claim 1 in which the gas containment reactor vessel is constructed of a microwave-transparent material and is located within the said waveguide.

3. The system according to claim 1 in which the gas containment reactor vessel is a metallic cavity which is coupled to the said waveguide by means of an aperture.

4. The system according to claim 1 in which the gas containment reactor vessel is a metallic cavity which is coupled to the said waveguide by means of an electrically conductive post.

5. The system according to claim 1 in which the microwave energy is in the frequency range of 300 MHz to 30 GHz.

6. The system according to claim 1 in which the microwave energy is in one of the Industrial, Scientific and Medical (ISM) bands, more specifically at or proximate to 915 MHz or 2450 MHz.

7. The system according to claim 1 in which multiple microwave sources may be connected to the same reactor vessel.

8. A system for processing gaseous materials through the use of microwave non-equilibrium plasmas, said system comprising
a) a microwave source connected to a waveguide,
b) a means of coupling said microwave energy from the waveguide to a vessel acting as a gas containment reactor vessel in which the plasma is generated and maintained,
c) a means of directing reagent gas into the said reactor vessel by means of supersonic nozzle gas expansion, and
d) a means of directing the post-plasma gas products stream into a second gas containment reactor vessel in which catalyst materials are arranged to facilitate direct contact between the gas products and the catalyst materials.

9. The system according to claim 8 in which the catalyst is in the form of a monolithic, gas-permeable matrix.

10. The system according to claim 8 in which the catalyst material is an inhomogeneous structure comprising an inert support matrix and an active metallic catalyst.

11. The system according to claim 8 in which the second gas containment reactor vessel operates as a fluidized bed.

12. A system for processing gaseous materials through the use of selective microwave heating, said system comprising
a) a microwave source connected to a waveguide,
b) a means of coupling said microwave energy from the waveguide to a gas containment reactor vessel containing catalyst material,
c) a means of controlling the microwave energy distribution within the reactor vessel so as to beneficially heat the catalyst material,
d) a means of directing reagent gas into the reactor vessel so as to make direct contact with the catalyst material, and
e) a means of directing the reaction gas products from the reactor vessel for further processing or discharge.

13. The system according to claim 12 in which the reactor vessel operates as a fluidized bed.
